(19) United States
(12) Patent Application Publication
(10) Pub. No.: US 2013/0320375 A1
(43) Pub. Date: Dec. 5, 2013

(54) OPTOELECTRONIC DEVICE AND METHOD FOR FORMING THE SAME

(71) Applicant: DELTA ELECTRONICS, INC., Taoyuan Hsien (TW)

(72) Inventors: Horng-Jou WANG, Taoyuan Hsien (TW); Shao-Yu CHEN, Taoyuan Hsien (TW); Shi-Yu WENG, Taoyuan Hsien (TW)

(73) Assignee: DELTA ELECTRONICS, INC., Taoyuan Hsien (TW)

(21) Appl. No.: 13/896,855

(22) Filed: May 17, 2013

(30) Foreign Application Priority Data
May 29, 2012 (TW) 101119031

(51) Int. Cl. H01L 33/58; H01L 31/0232

(52) U.S. Cl. CPC H01L 33/58; H01L 31/0232
USPC 257/98; 257/432; 438/27; 438/65

(57) ABSTRACT

According to an embodiment of the invention, an optoelectronic device is provided. The optoelectronic device includes: a lead frame having a reflective structure, wherein the reflective structure has an opening; an optoelectronic element disposed in the opening; at least one electrode disposed in the lead frame and electrically connected to the optoelectronic element; a lens disposed on the lead frame and having an adhesive portion having a holding surface, an alignment surface, and an adhesive surface, wherein the adhesive surface has a convex surface or a concave surface; and a covering adhesive layer filling a region defined by the reflective structure, covering the optoelectronic element, and adhering the lens to the lead frame through the adhesive portion of the lens.

### CROSS REFERENCE TO RELATED APPLICATIONS

This Application claims priority of Taiwan Patent Application No. 101119031, filed on May 29, 2012, the entirety of which is incorporated by reference herein.

### BACKGROUND OF THE INVENTION

1. Field of the Invention

The invention relates to an optoelectronic device, and in particular relates to a light emitting diode device.

2. Description of the Related Art

Optical lenses are often disposed on optoelectronic devices for assisting with light transmission. Typically, the optical lens is adhered onto a lead frame through an adhesive layer.

However, when an optical lens is adhered onto a lead frame, problems of tilt or dislocation may easily arise, which cause differences in light transmission and negatively affect the performance of the optoelectronic device.

Thus, it is desired to have technique to resolve and/or reduce the above-mentioned problems.

### BRIEF SUMMARY OF THE INVENTION

According to an embodiment of the invention, an optoelectronic device is provided. The optoelectronic device includes: a lead frame having a reflective structure, wherein the reflective structure has an opening; an optoelectronic element disposed in the opening; at least one electrode disposed in the lead frame and electrically connected to the optoelectronic element; a lens disposed on the lead frame and having an adhesive portion having a holding surface, an alignment surface, and an adhesive surface, wherein the adhesive surface has a convex surface or a concave surface; and a covering adhesive layer filling a region defined by the reflective structure, covering the optoelectronic element, and adhering the lens to the lead frame through the adhesive portion of the lens.

According to an embodiment of the invention, an optoelectronic device is provided. The optoelectronic device includes: a lead frame having a reflective structure, wherein the reflective structure has an opening; an optoelectronic element disposed in the opening; at least one electrode disposed in the lead frame and electrically connected to the optoelectronic element; a lens disposed on the lead frame and having an adhesive portion having a holding surface, an alignment surface, and an adhesive surface, wherein the adhesive surface has an adhesive sidewall and an adhesive bottom surface; and a covering adhesive layer filling a region surrounded by the reflective structure and covering the optoelectronic element, wherein the lens is adhered to the lead frame through the adhesive portion of the lens.

According to an embodiment of the invention, a method for forming an optoelectronic device is provided. The method includes: providing a lead frame; disposing an optoelectronic element on the lead frame; filling a covering adhesive layer in a region surrounded. by the reflective structure, wherein the covering adhesive layer covers the optoelectronic element; disposing a lens on an opening of the lead frame and the covering adhesive layer, wherein the lens has a holding surface, an alignment surface and an adhesive surface, and the adhesive surface has a convex surface or a concave surface; and curing the covering adhesive layer.

According to an embodiment of the invention, a method for forming an optoelectronic device is provided. The method includes: providing a lead frame; disposing

an optoelectronic element on the lead frame; filling a covering adhesive layer in a region surrounded by the reflective structure, wherein the covering adhesive layer covers the optoelectronic element; disposing a lens on an opening of the lead frame and the covering adhesive layer, wherein the lens has a holding surface, an alignment surface and an adhesive surface, wherein the adhesive surface has an adhesive sidewall and an adhesive bottom surface; and curing the covering adhesive layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1C are cross-sectional views of a manufacturing process of an optoelectronic device according to an embodiment of the present invention;

FIG. 2 is a cross-sectional view of a lens according to an embodiment. of the present invention; and

FIGS. 3A-3C are cross-sectional views of optoelectronic devices according to embodiments of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The manufacturing method and method for use of the embodiment of the invention are illustrated in detail as follows. It is understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

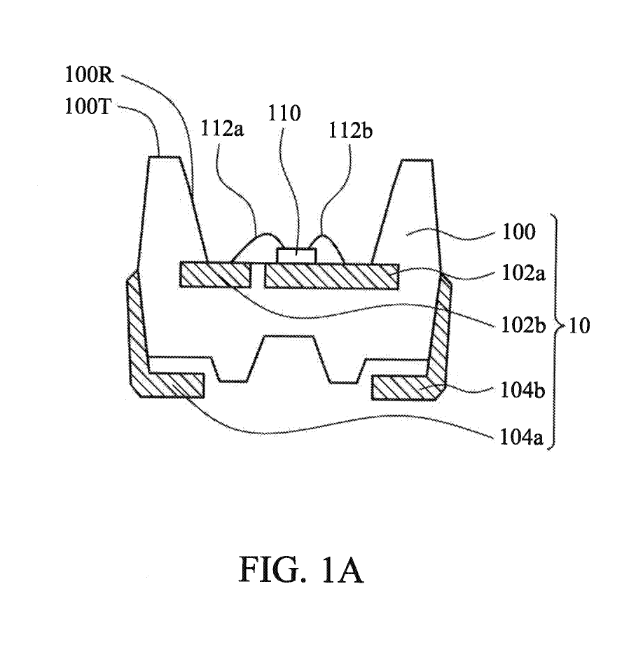

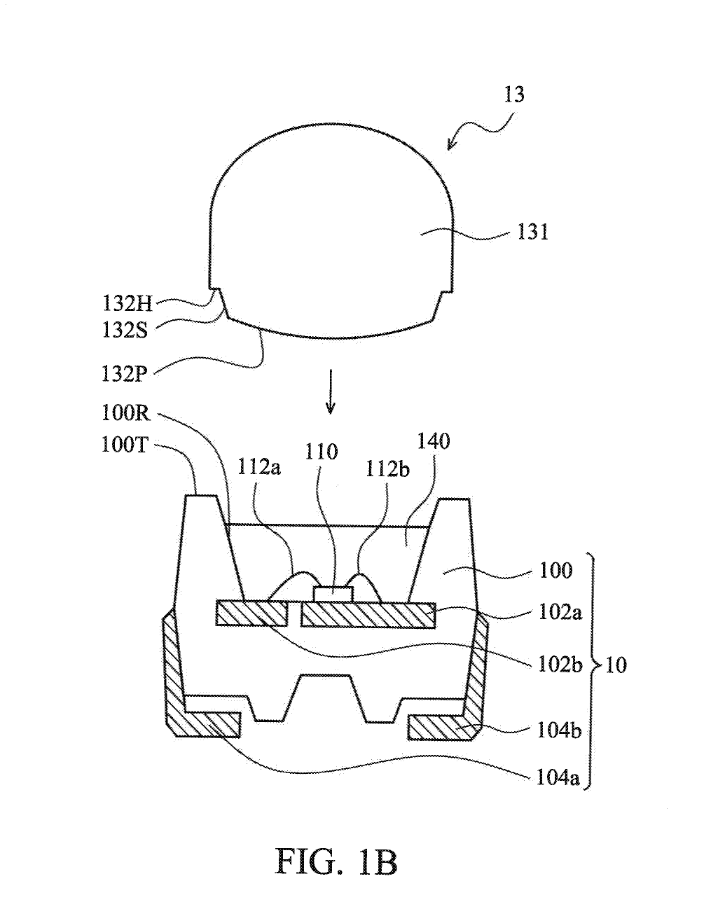

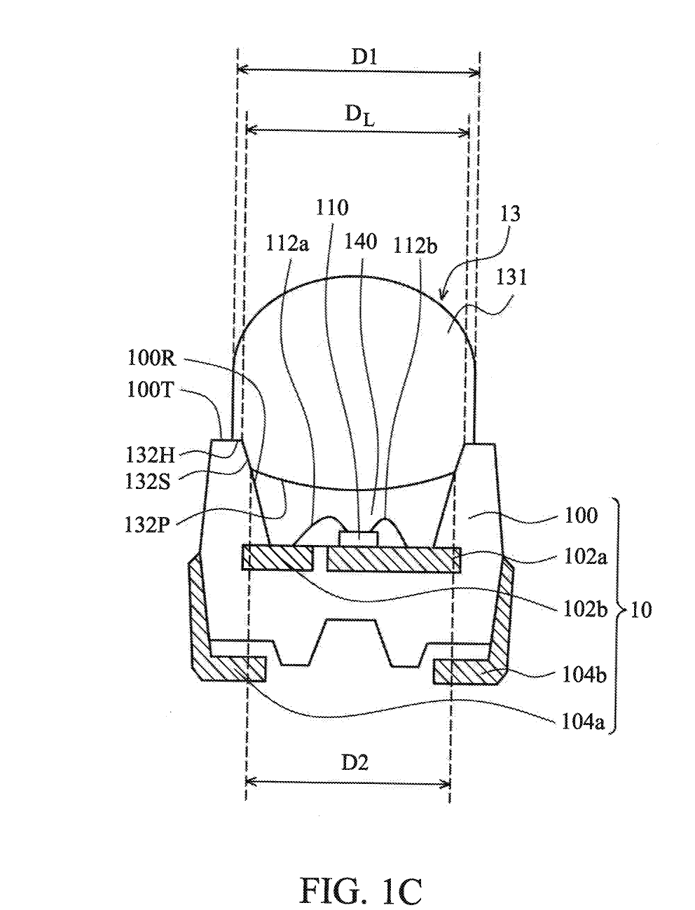

FIGS. 1A-1C are cross-sectional views of a manufacturing process of an optoelectronic device according to an embodiment of the present invention. As shown in FIG. 1A, the optoelectronic device has a lead frame 10, and the lead frame 10 includes a reflective structure 100. The reflective structure 100 can include plastics, silicone resin, epoxy resin, multiple coatings, polymer material, ceramic material, semiconductor material, metal material, or combinations thereof. The reflective structure 100 has an opening.

The optoelectronic device includes an optoelectronic element 110 disposed in the opening of the reflective structure 100. The optoelectronic element 110 can be a light emitting element (e.g. a light emitting diode) or a light sensing element. Taking a light emitting diode as an example, the optoelectronic element 110 has a P-type electrode and a N-type electrode (not shown), wherein the P-type electrode and the N-type electrode are electrically connected to conductive regions 102a and 102b of the lead frame 10 through the conductive wires 112a and 112b (e.g. by wire bonding or flip chip bonding), respectively. The conductive regions 102a and 102b are electrically connected to the electrodes 104a and 104b disposed on the lead frame 10 through conductive wires (not shown).

Then, as shown in FIG. 1B, the covering adhesive layer 140 is filled in a region surrounded by the reflective structure 100 to cover the optoelectronic element 110. The covering adhesive layer 140 has good light transmittance and good adhesion. The covering adhesive layer 140 can include silicone resin, epoxy resin, glass, or combinations thereof. The covering adhesive layer 140 can include other suitable transparent polymer materials. The covering adhesive layer 140 can be used to protect the optoelectronic element 110 and to adhere to and fix the lens 13, which will be installed in a subsequent process.

The lens 13 includes silicone resin, epoxy resin, glass, or combinations thereof. Alternatively, the lens 13 can include other suitable transparent materials. The lens 13 includes an output light portion 131, and the output light portion 131 has a convex profile (or a convex shape) or a concave profile (or a concave shape). The lens 13 includes an adhesive portion, and the adhesive portion has a holding surface 132H, an alignment surface 132S and an adhesive surface 132P.

Then, the lens 13 is disposed on the reflective structure 100, and the lens 13 can be embedded in and fixed to the covering adhesive layer 140, as shown in FIG. 1C. After the disposing of the lens 13, the covering adhesive layer 140 can optionally be cured. The curing of the covering adhesive layer 140 further includes a step of performing a light curing process, a thermal curing process, a room-temperature curing process, or combinations thereof to the covering adhesive layer 140.

The disposing of the lens 13 on the reflective structure 100 includes the steps of contacting the holding surface 132H of the lens 13 with a surface 100T of the reflective structure 100, and putting the alignment surface 132S into the opening along a sidewall 100R of the reflective structure 100.

As shown in FIG. 1C, the holding surface 132H of the lens 13 is on the surface 100T of the reflective structure 100. The holding surface 132H can be in direct contact with the surface 100T of the reflective structure 100. Alternatively, other material layers can be formed between the holding surface 132H and the surface 100T of the reflective structure 100. The reflective structure 100 can support the holding surface 132H so as to maintain the lens 13 in a suitable position. The holding surface 132H can be an annular plane. A maximum width D1 of the holding surface 132H is greater than a width D_{L} of the opening of the reflective structure 100. The holding surface 132H can be substantially parallel to the surface 100T of the reflective structure 100. A maximum width D2 of the adhesive surface 132P is less than a width D_{L} of the opening of the reflective structure 100.

The alignment surface 132S of the lens 13 can be used to help the alignment of the lens 13. The lens 13 moves downwardly along the sidewall 100R of the reflective structure 100. The alignment surface 132S can be substantially parallel to the sidewall 100R of the reflective structure 100. The alignment surface 132S can be in direct contact with the sidewall 100R of the reflective structure 100. Alternatively, other material layers can be formed between the alignment surface 132S and the sidewall 100R of the opening. The alignment surface 132S connects the holding surface 132H.

The adhesive surface 132P of the lens 13 extends from the alignment surface 132S to the optoelectronic element 110. The adhesive surface 132P is in direct contact with the covering adhesive layer 140. The adhesive surface 132P includes a convex surface or a concave surface. The adhesive surface 132P of the lens 13 helps the lens 13 to be pressed into the covering adhesive layer 140 and avoids and/or reduces the generation of bubbles in the covering adhesive layer 140. Thus, light can be successfully transmitted out from the optoelectronic element 110, or light can be successfully transmitted from the environment into the optoelectronic element 110.

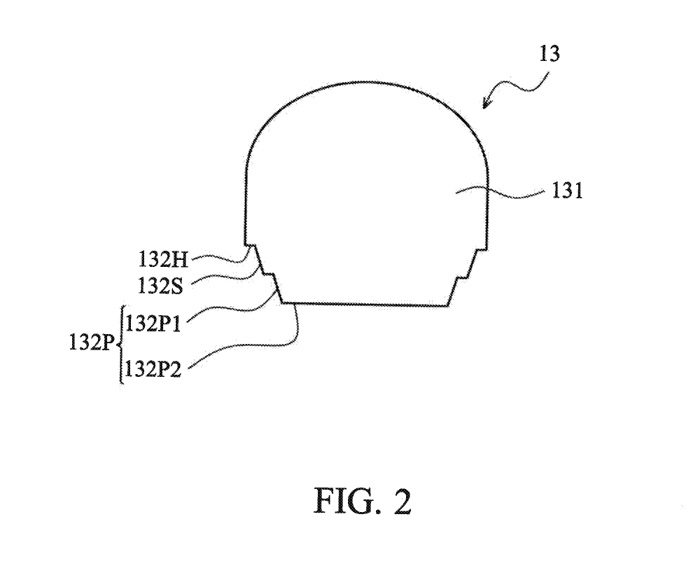

FIG. 2 is a cross-sectional view of a lens according to an embodiment of the present invention, wherein the same or similar reference numbers are used to designate the same or similar elements. The lens 13 of the embodiment of FIG. 2 is similar to the lens 13 of the embodiment of FIG. 1C except that the adhesive surface 132P of the lens 13 of FIG. 2 further includes an adhesive sidewall 132P1 and an adhesive bottom surface 132P2. The adhesive bottom surface 132P2 is substantially a plane, a convex surface, or a concave surface. The lens 13 shown in FIG. 2 can replace the lens 13 of the embodiment of FIG. 1C. In this case, the adhesive bottom surface 132P2 is substantially parallel to the surface 100T of the reflective structure 100, but the invention is not limited thereto.

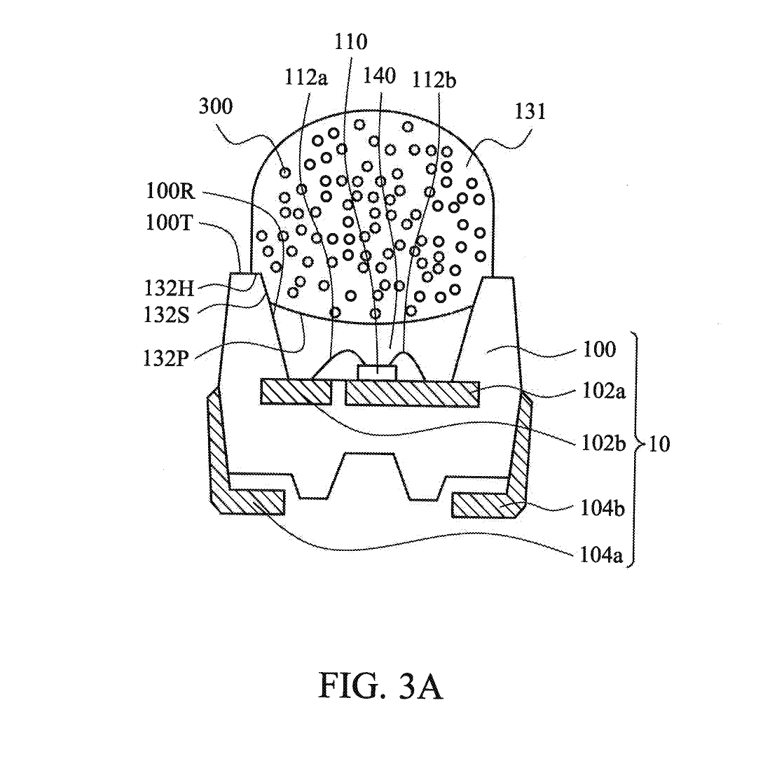

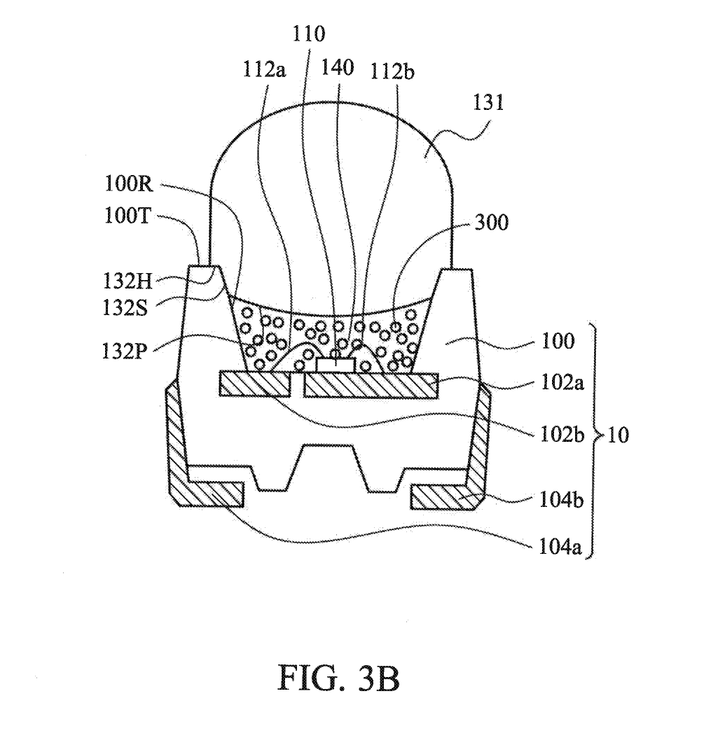

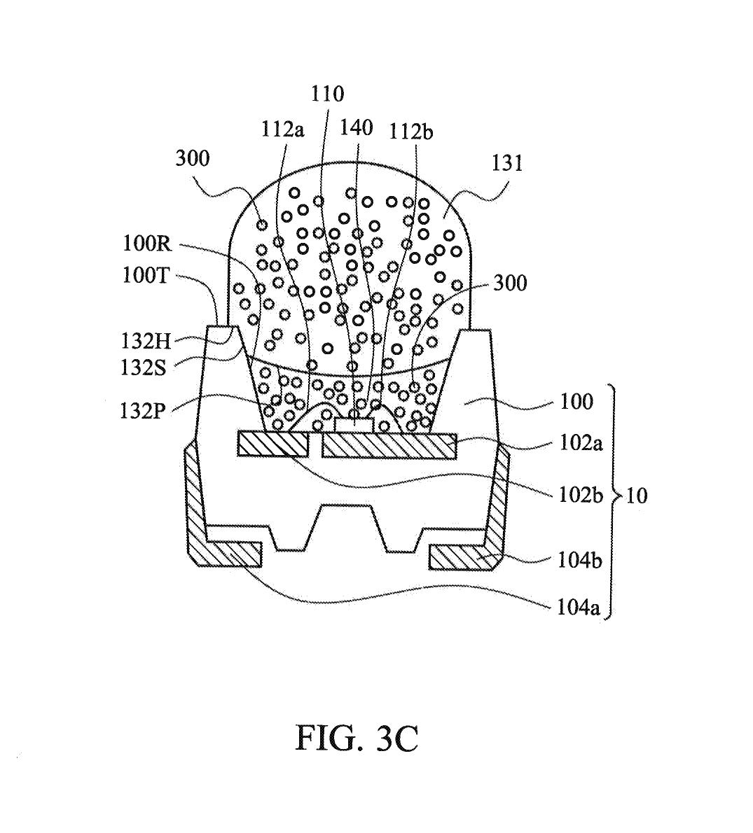

FIGS. 3A-3C are cross-sectional views of optoelectronic devices according to other embodiments of the present invention, wherein same or similar reference numbers are used to designate same or similar elements. In the embodiments, a plurality of optical wavelength converting particles and/or a plurality of optical diffusion particles can be introduced into the optoelectronic device. For example, particles 300 are disposed in the lens 13, as shown in FIG. 3A. Alternatively, the particles 300 can be disposed in the covering adhesive layer 140, as shown in FIG. 3B. Alternatively, the particles 300 can be disposed in the lens 13 and the covering adhesive layer 140, as shown in FIG. 3C. The suitable optical wavelength converting particles include, for example, yttrium aluminum garnet (YAG) fluorescence powder, silicate fluorescence powder, terbium aluminum garnet (TAG) fluorescence powder, oxide fluorescence powder, nitride fluorescence powder, aluminum oxide fluorescence powder, fluorescence powder and materials capable of converting optical wavelengths, or combinations thereof The suitable optical diffusion particles include, for example, silicon dioxide particles, aluminum oxide particles, calcium fluoride particles, calcium carbonate particles, barium sulfate particles, particles capable of diffusing light, or combinations thereof The lens 13 of the embodiment of FIG. 2 can be used to replace the lens of the embodiments of FIGS. 3A-3C.

The lens of the optoelectronic device of the embodiments of the invention has a specific adhesive portion, which can facilitate the self-alignment between the lens and the covering adhesive layer during the bonding of the lens to the covering adhesive layer, and thus the tilt of the lens and the mismatch of the lens and the covering adhesive layer can be reduced and/or be avoided, which helps the lens to be positioned accurately and set firmly onto the optoelectronic element. Moreover, the transmission error of light can be reduced, the performance of the device can be improved, the manufacturing process can be simplified, and the manufacturing cost can be reduced. Furthermore, the generation of bubbles in the covering adhesive layer can be effectively avoided by the design of the convex surface or the concave surface of the bottom of the lens so as to improve the performance of the optoelectronic device.

While the invention has been described by way of example and in terms of the preferred embodiments, it is to be understood that the invention is not limited to the disclosed embodiments. On the contrary, it intended to cover various modifications and similar arrangements (as would be apparent to those skilled in the art). Therefore, the scope of the appended claims should he accorded the broadest interpretation so as to encompass all such modifications and similar arrangements.

What is claimed is:

1. An optoelectronic device, comprising:
a lead frame having a reflective structure, wherein the reflective structure has an opening;
an optoelectronic element disposed in the opening;
at least one electrode disposed in the lead frame and electrically connected to the optoelectronic element;
a lens disposed on the lead frame and comprising an adhesive portion having a holding surface, an alignment surface, and an adhesive surface, wherein the adhesive surface has a convex surface or a concave surface; and
a covering adhesive layer filling a region surrounded by the reflective structure and covering the optoelectronic element, wherein the lens is adhered to the lead frame through the adhesive portion of the lens.

2. The optoelectronic device as claimed in claim I, wherein the reflective structure comprises plastics, silicone resin, epoxy resin, multiple coatings, polymer materials, ceramic materials, semiconductor materials, metal materials, or combinations thereof.

3. The optoelectronic device as claimed in claim I, wherein the holding surface is in direct contact with a surface of the reflective structure, the alignment surface is in direct contact with a sidewall of the reflective structure, and the covering adhesive layer is in direct contact with the adhesive surface of the lens.

4. The optoelectronic device as claimed in claim 1, wherein the optoelectronic element comprises a light emitting element or a light sensing element.

5. The optoelectronic device as claimed in claim 1, wherein the holding surface connects with the alignment surface, and the holding surface is an annular plane.

6. The optoelectronic device as claimed in claim 1, wherein the covering adhesive layer comprises silicone resin, epoxy resin, glass, transparent polymer materials, or combinations thereof.

7. The optoelectronic device as claimed in claim 1, wherein the lens comprises silicone resin, epoxy resin, glass, or combinations thereof

8. The optoelectronic device as claimed in claim 1, further comprising a plurality of optical wavelength converting particles or a plurality of optical diffusion particles disposed in the lens or the covering adhesive layer.

9. The optoelectronic device as claimed in claim 8, wherein the optical wavelength converting particles comprise yttrium aluminum garnet fluorescence powder, silicate fluorescence powder, terbium aluminum garnet fluorescence powder, oxide fluorescence powder, nitride fluorescence powder, aluminum oxide fluorescence powder, fluorescence powder and materials capable of converting optical wavelengths, or combinations thereof.

10. The optoelectronic device as claimed in claim 8, wherein the optical. diffusion particles comprise silicon dioxide particles, aluminum oxide particles, calcium fluoride particles, calcium carbonate particles, barium sulfate particles, particles capable of diffusing light, or combinations thereof.

11. The optoelectronic device as claimed in claim 1, wherein a maximum width of the holding surface is greater than a width of the opening of the reflective structure.

12. The optoelectronic device as claimed in claim 1, wherein a maximum width of the adhesive surface is less than a width of the opening of the reflective structure.

13. An optoelectronic device, comprising:
a lead frame having a reflective structure, wherein the reflective structure has an opening;
an optoelectronic element disposed in the opening;
at least one electrode disposed in the lead frame and electrically connected to the optoelectronic element;
a lens disposed on the lead frame and comprising an adhesive portion having a holding surface, an alignment surface, and an adhesive surface, wherein the adhesive surface has an adhesive sidewall, and an adhesive bottom surface; and
a covering adhesive layer filling a region surrounded by the reflective structure and covering the optoelectronic element, wherein the lens is adhered to the lead frame through the adhesive portion of the lens.

14. The optoelectronic device as claimed in claim 13, wherein the adhesive bottom surface comprises a plane, a convex surface, or a concave surface.

15. The optoelectronic device as claimed in claim 13, wherein the reflective structure comprises plastics, silicone resin, epoxy resin, multiple coatings, polymer materials, ceramic materials, semiconductor materials, metal materials, or combinations thereof.

16. The optoelectronic device as claimed in claim 13, wherein the holding surface is in direct contact with a surface of the reflective structure, the alignment surface is in direct contact with a sidewall of the reflective structure, and the covering adhesive layer is in direct contact with the adhesive surface of the lens.

17. The optoelectronic device as claimed in claim 13, wherein the holding surface connects with the alignment surface, and the holding surface is a annular plane.

18. The optoelectronic device as claimed in claim 13, wherein the covering adhesive layer comprises silicone resin, epoxy resin, glass, transparent polymer materials, or combinations thereof.

19. The optoelectronic device as claimed in claim 13, further comprising a plurality of optical wavelength converting particles or a plurality of optical diffusion particles disposed in the lens or the covering adhesive layer.

20. The optoelectronic device as claimed in claim 19, Wherein the optical wavelength converting particles comprises yttrium aluminum garnet fluorescence powder, silicate fluorescence powder, terbium aluminum garnet fluorescence powder, oxide fluorescence powder, nitride fluorescence powder, aluminum oxide fluorescence powder, fluorescence powder and materials capable of converting optical wavelengths, or combinations thereof.

21. The optoelectronic device as claimed in claim 19, wherein the optical diffusion particles comprise silicon dioxide particles, aluminum oxide particles, calcium fluoride particles, calcium carbonate particles, barium sulfate particles, particles capable of diffusing light, or combinations thereof.

22. The optoelectronic device as claimed in claim 13, wherein a maximum width of the holding surface is greater than a width of the opening of the reflective structure, and a maximum width of the adhesive surface is less than a width of the opening of the reflective structure.

23. A manufacturing method of an optoelectronic device, comprising:
providing a lead frame;
disposing an optoelectronic element on the lead frame;
filling a covering adhesive layer in a region surrounded by the reflective structure, wherein the covering adhesive layer covers the optoelectronic element;
disposing a lens on an opening of the lead frame and the covering adhesive layer, wherein the lens comprises a holding surface, an alignment surface and an adhesive surface, and the adhesive surface has a convex surface or a concave surface; and
curing the covering adhesive layer.

24. The manufacturing method of the optoelectronic device as claimed in claim 23, wherein the curing of the covering adhesive layer comprises performing a light curing process, a thermal curing process, a room-temperature curing process, or combinations thereof to the covering adhesive layer.

25. A manufacturing method of an optoelectronic device, comprising:
providing a lead frame;
disposing an optoelectronic element on the lead frame;
filling a covering adhesive layer in a region surrounded by the reflective structure, wherein the covering adhesive layer covers the optoelectronic element;
disposing a lens on an opening of the lead frame and the covering adhesive layer, wherein the lens comprises a holding surface, an alignment surface and an adhesive surface, wherein the adhesive surface has an adhesive sidewall and an adhesive bottom surface; and
curing the covering adhesive layer.

26. The manufacturing method of the optoelectronic device as claimed in claim 25, wherein the adhesive bottom surface comprises a plane, a convex surface, or a concave surface.

27. The manufacturing method of the optoelectronic device as claimed in claim 25, wherein the curing of the covering adhesive layer comprises performing a light curing process, a thermal curing process, a room-temperature curing process, or combinations thereof to the covering adhesive layer.
